(19) United States
(12) Patent Application Publication
(10) Pub. No.: US 2007/0222335 A1
(43) Pub. Date: Sep. 27, 2007

(54) SURFACE ACOUSTIC WAVE DEVICE

(75) Inventors: Masahiro NAKANO, Tokyo (JP); Takashi Osada, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: TDK CORPORATION, Tokyo (JP)

(21) Appl. No.: 11/681,510

(22) Filed: Mar. 2, 2007

(30) Foreign Application Priority Data
Mar. 22, 2006 (JP) 2006-079201
Nov. 30, 2006 (JP) 2006-323991

(51) Int. Cl. H03H 9/25

(52) U.S. Cl. 310/313 A

(57) ABSTRACT

A SAW device includes one or more surface acoustic wave element which comprises an interdigital transducer on a single crystal piezo-electric substrate and is flip-chip mounted on a base substrate through metal bumps. The IDT transducer is formed of a laminate film including an underlying layer made of titanium nitride or titanium and an aluminum layer. The underlying layer and Al layer are laminated sequentially on the single crystal piezo-electric substrate. The single crystal piezo-electric substrate is a 46°- or more rotation Y-cut X-propagation lithium tantalate substrate. The single crystal piezo-electric substrate may be a 64°-rotation Y-cut X-propagation lithium niobate substrate.

### BACKGROUND OF THE INVENTION

The present invention relates to a surface acoustic wave device, and more particularly, to the structure of a surface acoustic wave device which is flip-chip mounted through metal bumps.

SAW devices which utilize surface acoustic waves (hereinafter called “SAW” in some cases) generated by the piezo-electric effect are widely used in recent years for resonators, filters, duplexers and the like because of their small sizes and light weights as well as suitability for higher performance.

Such a SAW device is generally created by forming a chip-shaped SAW element having a plurality of interdigital transducers (hereinafter called “IDT” in some cases) for exciting acoustic surface waves on the surface of a piezo-electric single crystal substrate made of lithium tantalate (LitaO₃), lithium niobate (LiNbO₃) or the like, mounting the SAW element on a base substrate, and hermetically sealing the resulting assembly.

The following patent documents also disclose such SAW devices:

Patent Document 1: JP-A-2003-101372;

Patent Document 2: WO99/16168; and

Patent Document 3: JP-A-2005-039676.

### SUMMARY OF THE INVENTION

For example, an antenna duplexer, which is one of SAW devices, is provided in an RF unit (radio frequency unit) of a mobile phone, and is required to provide high power resistance performance because it is positioned at a rear stage of a transmission amplifier, and is applied with large power.

For this reason, in Patent Document 1 (JP-A-2003-101372), the power resistance is improved by forming IDT which is made of an epitaxially grown aluminum single crystal film. Also, the formation of such a transducer film based on epitaxial aluminum requires a buffer layer (underlying layer) for alignment to the lattice of a single crystal piezo-electric substrate, so that Patent Document 1 describes that an underlying film made of titanium nitride is disposed on a piezo-electric substrate, followed by the formation of an aluminum single crystal film on the underlying film. Likewise, in the aforementioned Patent Document 2 (WO99/16168) and Patent Document 3 (JP-A-2005-39676), a buffer layer made of titanium nitride or titanium is disposed on a lithium tantalate or a lithium niobate substrate, followed by the formation of an aluminum single crystal film on the buffer layer.

It is generally known that when a thin film is epitaxially grown on a single crystal underlying layer made of a different material, the alignment of lattice is mitigated by defects (for example, point defect, lamination defect, dislocation, twin crystal and the like) of the thin film. However, though the thin film can exist as a stable epitaxial film, a large internal stress is generated within the thin film until defects are formed. Therefore, once a stress is applied from the outside after deposition, the epitaxial thin film itself is broken, or the underlying layer is broken, possibly resulting in damages that can disable functions of a final device.

Such a break of the thin film caused by the misalignment of lattice has not constituted a problem in a traditional mounting structure which involved wire bonding of SAW chips. However, due to requirements for a reduction in size and thickness of SAW devices, the mounting of SAW chips onto a base substrate is shifting from the traditional die bonding and wire bonding methods to a flip chip bonding (hereinafter called “FCB” in some cases) method which does not require an area or a height for routing wires.

The FCB mounting involves thermocompression bonding of gold bumps, for example, on a gold plated base substrate additionally using ultrasonic waves. For mounting, a SAW chip which has an epitaxial aluminum transducer formed on a single crystal piezo-electric substrate is electrically connected to connection pads on a base substrate, and simultaneously, the chip must be mechanically held on the base substrate. For mechanically holding the SAW chip on the base substrate, the SAW chip is required to exhibit a strength which permits the SAW chip to withstand impacts applied to a product as well as thermal impacts during solder reflowing. Moreover, the epitaxial film on the SAW chip implies a large internal stress due to the misalignment of lattice as mentioned above, and is applied with the foregoing impacts (impacts applied to the product and thermal impacts during solder reflowing) in addition to the internal stress.

The inventors fabricated multiple samples of SAW devices for testing and investigations, and recognized cracks (rupture) in a region of a piezo-electric substrate in which gold bumps were formed, in a region around the substrate region, or in IDT transducer films. Such defects are presumably caused by the internal stress as mentioned above. Then, such cracks can cause degraded electric characteristics of the SAW device and failures due to broken lines, possibly damaging the reliability of the SAW device.

It is therefore an object of the present invention to solve the problems mentioned above to more improve the reliability of a SAW device which has an FCB-mounted SAW element.

To solve the problems and achieve the object, a first surface acoustic wave device of the present invention includes one or more surface acoustic wave element which comprises an interdigital transducer on a single crystal piezo-electric substrate and is flip-chip mounted on a base substrate through metal bumps, wherein the interdigital transducer is formed of a laminate film including an underlying layer made of titanium nitride or titanium and an aluminum layer, the underlying layer and the aluminum layer being laminated sequentially on the single crystal piezo-electric substrate, and the single crystal piezo-electric substrate is a 46°- or more rotation Y-cut X-propagation lithium tantalate substrate.

A second surface acoustic wave device of the present invention includes one or more surface acoustic wave element which comprises an interdigital transducer on a single crystal piezo-electric substrate and is flip-chip mounted on a base substrate through metal bumps, wherein the interdigital transducer is formed of a laminate film including an underlying layer made of titanium nitride or titanium and an aluminum layer, the underlying layer and the aluminum layer being laminated sequentially on the single crystal piezo-electric substrate, and the single crystal piezo-electric substrate is a 64°-rotation Y-cut X-propagation lithium niobate substrate.

As has been previously stated, when a SAW element is FCB mounted, the misalignment of lattice of an epitaxial film causes a large internal stress in a thin film which causes a break in the epitaxial film, a break in an underlying single crystal piezo-electric substrate, together with a mechanical or a thermal impact added thereto, possibly resulting in damages that can disable functions of the SAW device. The inventors have found, from the results of various investigations on a variety of methods for solving such a problem, that a particular high-cut substrate is advantageously used for the piezo-electric substrate which form the basis of the SAW element.

Specifically, FIGS. 1 to 6 are X-ray diffraction based pole diagrams of aluminum epitaxial films formed on single crystal piezo-electric substrates, where FIGS. 1 to 5 are pole diagrams of aluminum (111) epitaxially grown on buffer layers (TiN thin film) deposited on LiTaO₃ single-crystal piezo-electric substrates which are cut at right angles to new Y′-axes rotated by 36°, 39°, 46°, 48°, and 52°, respectively, from the Y-axis, and FIG. 6 is a pole diagram of aluminum (111) epitaxially grown on a buffer layer (TiN thin film) similarly deposited on a LiNbO₃ single-crystal piezo-electric substrate which is cut at right angles to a new Y′-axis rotated by 64° from the Y-axis. Detailed conditions for the deposition of the TiN thin film and aluminum epitaxial film will be described later in “DESCRIPTION OF THE EMBODIMENTS.”

In these diagrams, a point A represents a signal of the aluminum (111), while a point B represents a signal other than aluminum. The point B is also observed on the single crystal piezo-electric substrate before the deposition of the TiN thin film and aluminum film, and this location matches the direction of a Z-axis plane of the single crystal piezo-electric substrate. As can be seen from these pole diagrams, the difference between the location of the signal from the single crystal piezo-electric substrate and the location of the aluminum (111) depends on an angle (cut angle) by which a new Y′-axis is rotated from the Y-axis. In other words, it is thought that the misalignment of lattice differs depending on the cut angle of the piezo-electric substrate in a range of 36° to 52°. It is anticipated that the difference in misalignment results in a difference in internal stress of the epitaxial film, and the difference in internal stress gives rise to a difference in flip chip bonding strength and constitutes the cause of degrading the reliability of the SAW device.

The internal stress caused by the lattice misalignment of an epitaxial film is described as follows. Atoms in the epitaxial film are arranged at locations with low potentials in accordance with the arrangement of atoms on the surface of an underlying single crystal substrate. The locations determined by the arrangement are different from the lattice constant of the material for the epitaxial film, resulting in distortions in the arrangement of atoms in the epitaxial film. The film suffers from larger distortions from larger misalignment of the lattice constant of the underlying single crystal substrate to the lattice constant of the epitaxial film, resulting in an increase in the internal stress of the film.

The aluminum (111) plane epitaxially grows in parallel with the Z-axis plane of the underlying single crystal piezo-electric substrate by the action of a TiN thin film (buffer layer). It is thought that the Z-axis plane more parallel with the surface of the substrate results in less lattice misalignment, and a lower internal stress. Also, as the single crystal piezo-electric substrate is cut at a larger angle, a smaller angle is formed between the Z-axis plane and the surface of the substrate. From observations on the pole diagrams, it can be seen that as the piezo-electric substrate is cut at a larger angle, the elevation at the signal location, i.e., point B on the Z-axis plane of the piezo-electric substrate differs from the elevation at the signal location, i.e., point A on the aluminum (111) in a smaller angle range. At a cut angle of 46°, the elevation of the Z-axis plane of the piezo-electric substrate differs from the elevation of the aluminum (111) by 10° or less. Therefore, it is thought that as the piezo-electric substrate is cut at a larger angle beyond 46° (for example, in a range of 46° to 52° for LiTaO₃ substrates, and 64° for a LiNbO₃ substrate), the lattice misalignment is reduced between the single crystal piezo-electric substrate and aluminum, resulting in a smaller internal stress. A description will be given later in DESCRIPTION OF THE EMBODIMENTS in regard to the results of observations on cracks found in multiple samples fabricated using piezo-electric substrates having cut angles in the foregoing range.

Thus, the present invention employs a Y-cut X-propagation lithium tantalate substrate having a rotation angle of 46° or more (particularly, equal to or more than 46° and equal to or less than 52°) or a 64°-rotation Y-cut X-propagation lithium niobate substrate for a single crystal piezo-electric substrate used to form the basis of a SAW element. Then, an underlying layer (buffer layer) made of titanium nitride or titanium is disposed on the piezo-electric substrate, followed by the formation of an aluminum thin film patterned into an IDT transducer. In this way, when the SAW element is FCB mounted on a base substrate to manufacture a SAW device, the SAW device can be prevented from cracks and breaks in the piezo-electric substrate around locations at which bumps are bonded, and in the IDT transducer film, to improve the reliability of the SAW device.

Also, according to the present invention, since the transducer film can be formed of pure aluminum while increasing the power resistance without using an alloy which is a mixture of a transducer material with an additive (for example, Cu, Ti or the like) in order to improve the power resistance, as done in a conventional approach, the present invention can fabricate a SAW device which can avoid such problems as susceptibility of the IDT transducer to corrosion and increase in electric resistance, and the like, and exhibits a small insertion loss as well as good electric characteristics and corrosion resistance. Further, in the present invention, the aluminum layer, which comprises the IDT transducer, is preferably in a single crystal structure or a twin structure. The aluminum layer in such a structure can lend itself to the accomplishment of a SAW device which exhibits a small electric resistance, a low loss, a high efficiency, and a long effective life.

It should be understood that while the present invention is preferably applicable to SAW duplexers which are required to provide a high power resistance, the present invention is not limited to this particular application but can be applied, for example, to a variety of SAW filters such as bandpass filters, lowpass filters, high pass filters and the like, triplexers, and a variety of SAW devices which include one or more SAW elements that utilize surface acoustic waves.

According to the present invention, it is possible to improve the reliability of a SAW device which has a SAW element FCB mounted on a substrate.

Other objects, features, and advantages of the present invention will be made apparent from the following description of embodiments and examples of the present invention. It should be apparent to those skilled in the art that the present invention is not limited to these embodiments or examples, but can be modified in various manners without departing from the scope of the invention set forth in the claims.

### BRIEF DESCRIPTION OF THE DRAWINGS

FIG. 1 is a (111) pole diagram of an epitaxial aluminum layer deposited on 36°-rotation Y-X propagation LiTaO₃ single crystal piezo-electric substrate;

FIG. 2 is a (111) pole diagram of an epitaxial aluminum layer deposited on 39°-rotation Y-X propagation LiTaO₃ single crystal piezo-electric substrate;

FIG. 3 is a (111) pole diagram of an epitaxial aluminum layer deposited on 46°-rotation Y-X propagation LiTaO₃ single crystal piezo-electric substrate;

FIG. 4 is a (111) pole diagram of an epitaxial aluminum layer deposited on 48°-rotation Y-X propagation LiTaO₃ single crystal piezo-electric substrate;

FIG. 5 is a (111) pole diagram of an epitaxial aluminum layer deposited on 52°-rotation Y-X propagation LiTaO₃ single crystal piezo-electric substrate;

FIG. 6 is a (111) pole diagram of an epitaxial aluminum layer deposited on 64°-rotation Y-X propagation LiNbO₃ single crystal piezo-electric substrate; and

FIG. 7 is a conceptual diagram illustrating a SAW device according to one embodiment of the present invention.

### DESCRIPTION OF THE EMBODIMENTS

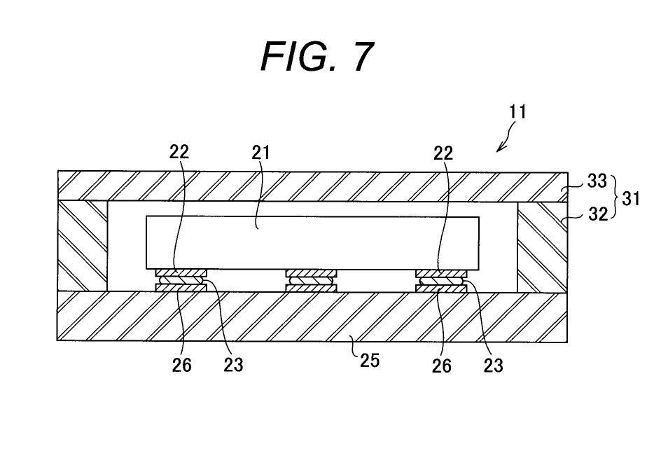

FIG. 7 illustrates a SAW device according to one embodiment of the present invention. As illustrated, this SAW device 11 comprises a SAW element 21 mounted on the surface of a base substrate 25, and a lid 31 which hermetically seals the surface of the base substrate 25 on which the SAW element 21 is mounted. The SAW element 21 may be FCB mounted on the base substrate 25 in a face-down orientation. Specifically, connection electrodes 22 formed on the SAW element 21 are bonded to connection pads 26 disposed on the base substrate 25 through metal bumps (for example, Au bumps) 23, thereby electrically and mechanically connecting the SAW element 21 to the base substrate 25. In this connection, when a duplexer is created, for example, two SAW elements 21 (a transmission SAW element and a reception SAW element) having center frequencies different from each other are mounted on the base substrate 25.

In the creation of the SAW element 21, a thin film made of TiN (or Ti) is formed on the surface of a 46°-rotation Y-X propagation LiTaO₃ single crystal piezo-electric substrate by epitaxial growth for use as a buffer layer, and an Al thin film is further epitaxially grown on the thin film to form a transducer film which is then patterned into an IDT transducer using the photolithography and dry etching techniques.

It should be noted that the piezo-electric substrate may be a LiTaO₃ single crystal piezo-electric substrate which has any cut angle in a range of 46° to 52°, and a 64°-rotation Y-X propagation LiNbO₃ single crystal piezo-electric substrate can be used as well. The use of single crystal piezo-electric substrates having such cut angles can reduce the misalignment of crystal lattice between the single crystal piezo-electric substrate and transducer film (Al thin film) to keep an internal stress small, thus preventing the piezo-electric substrate and IDT transducer from cracking. Also, while the Al thin film is preferably has a single crystal structure in order to accomplish a high power resistance, a perfect single crystal structure may not be necessarily required (for example, the Al thin film may have a twin structure, a polycrystalline structure with less crystal grain boundaries, or the like).

A plurality of connection pads 22 are formed on the surface of the piezo-electric substrate, on which the transducer film has been formed, for FCB mounting the SAW element 21 on the base substrate 25. A predetermined number of connection pads 22 are formed, for example, by depositing a Cr (chrome) thin film, laminating an Al thin film on the Cr thin film, and patterning these thin films into the connection pads 22 using the photolithography and dry etching techniques. Then, Au balls are ultrasonically bonded to these connection pads 22 to form metal bumps 23 for FCB mounting. It should be noted that in the formation of the SAW element 21 (IDT, connection pads), a plurality of SAW elements may be simultaneously formed on a single piezo-electric wafer, and the respective elements thus formed may be diced into individual chip-shaped SAW elements.

The base substrate 25 may be made of any composite material which is resin, ceramic or a mixture of resin and a filler and the like, and is not particularly limited in constituent materials. Terminals (not shown) for connection to the outside are disposed on the bottom surface of the base substrate 25 (opposite to the side on which the SAW element 21 is mounted). Further, a variety of elements, wires, ground electrodes and the like can be disposed on the top and bottom surfaces and internal wiring layers of the base substrate 25. The lid 31 in turn comprises a frame (so-called dam) 32, disposed on the base substrate 25 to surround the SAW element 21 for defining a space for accommodating the SAW element 21; and a top plate 33 carried on the frame 32 to close the top of the space, and hermetically seals the SAW element 21 mounted on the base substrate 25.

### EXAMPLES

Next, examples of the present invention will be described.

Each of 36°, 39°, 46°, 48°, and 52°-rotation Y-X propagation LiTaO₃ single crystal piezo-electric substrates was washed by a pure water brush washer, and a TiN film and an Al film were deposited on the surface of the substrate by a sputtering machine in the order of TiN and Al. In this event, the TiN film was deposited in a thickness of 4 nm using a metal Ti target under the condition that Ar and N₂ were supplied in a ratio of 50:50 at a gas flow rate which was adjusted to generate a pressure of 0.5 Pa, and the power applied to the target was controlled to be DC 0.2 kW with a power density of approximately 0.1 W/cm². After forming the TiN film, the four types of single crystal piezo-electric substrates were carried into an Al deposition chamber, while kept in vacuum, to deposit an Al film thereon. The Al film was deposited using an Al target having the purity 6N under the condition that an Ar gas was supplied at a flow rate which was adjusted to generate a pressure of 0.5 Pa, and power applied to the target was DC 2 kW with the power density of approximately 1 W/cm².

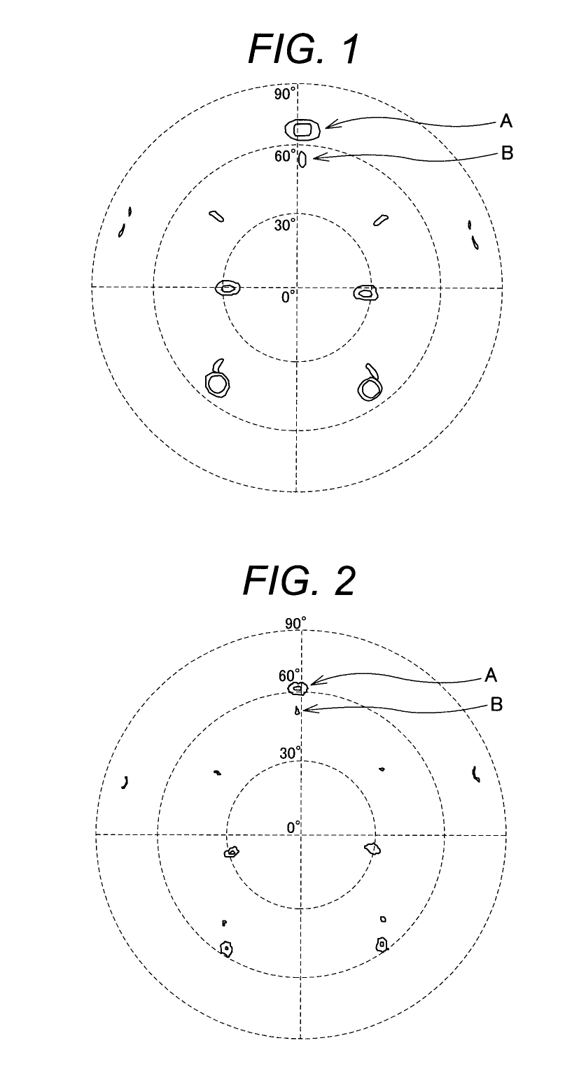

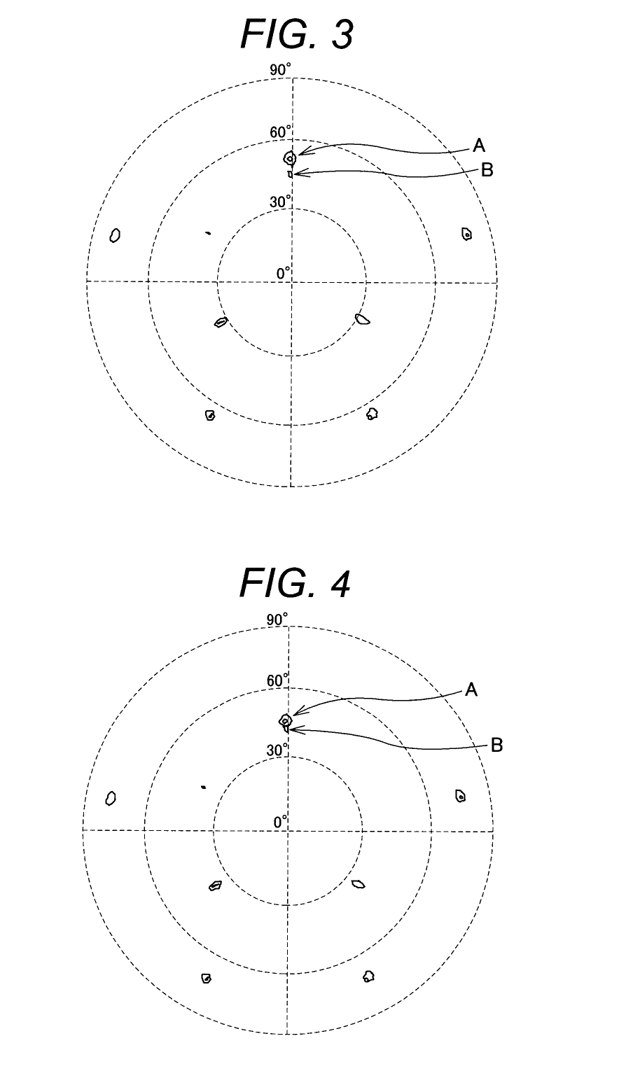

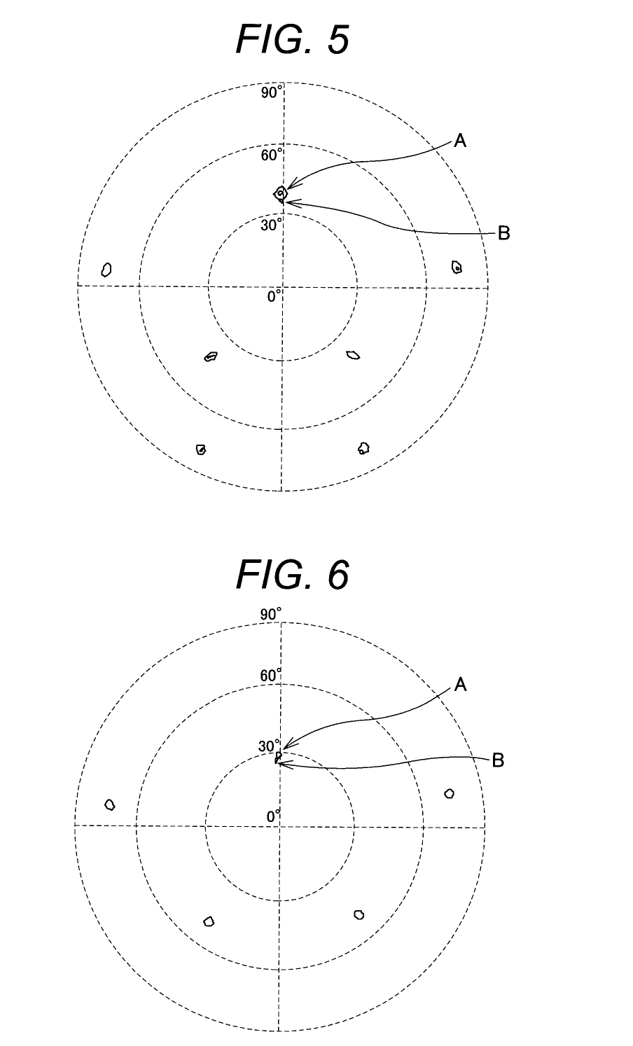

Then, the crystallinity of the deposited Al films was evaluated by X-ray diffraction. The results are shown in respective pole diagrams in FIGS. 1 to 5 (FIG. 1: 36°, FIG. 2: 39°, FIG. 3: 46°, FIG. 4: 48°, FIG. 5: 52°). Likewise, a TiN film and Al film were deposited on a 64°-rotation Y-X propagation LiNbO₃ single crystal piezo-electric substrate in a similar manner for evaluation on the crystallinity of the Al film by the X-ray diffraction. The result is shown in the aforementioned pole diagram of FIG. 6.

The epitaxial Al films and TiN films thus formed were simultaneously patterned into IDTs, each of which would form part of a SAW resonator, in a plurality of SAW element formation areas using the photolithography and dry etching techniques. Subsequently, a Cr (chrome) film and an Al film were deposited in this order for forming connection pads (conductive pads) on which Au bumps would be disposed for FCB mounting, and were formed into the connection pads using the photolithography and dry etching techniques. Then, Au bumps were disposed on the connection pads by ultrasonically bonding Au balls. The Au bumps were deposited under the condition that ultrasonic power was 148 mW, a load was 50 g, and an ultrasonic wave was applied for a duration of 30 msec. Each SAW element was provided with six Au bumps, and subsequently, the respective SAW elements were diced from a wafer into individual chip-shaped SAW elements.

On the other hand, a flip-chip mounted base substrate was prepared by forming Ni/Au plated electrodes on a glass epoxy substrate, and washing the substrate using plasma to clean the surface. The chip-shaped SAW element was placed on the base substrate such that the Au bumps came into contact with the Ni/Au plated surface, and was FCB mounted through ultrasonic thermocompression bonding. The FCB mounting was performed under the condition that ultrasonic power was 500 mW, a load was 500 g, an ultrasonic wave was applied for a duration of 100 msec, and the temperature of a stage for heating the base substrate was 150° C.

Regions around the connection pads of the thus FCB mounted SAW elements were observed from the back side of the Au bump formed surfaces to count the number of cracks in that regions of the single crystal piezo-electric substrates. It is strongly desired to prevent such cracks in the single crystal piezo-electric substrates because they can reduce the mechanical strength of the FCB mounting and extremely degrade the impact resistance and thermal impact resistance to disable functions of products.

Table 1 below shows the number of cracks in the substrates in the regions around the pads of the SAW elements using the aforementioned six types of single crystal piezo-electric substrates.

TABLE 1

| | | NUMBER OF PADS | |
|---|---|---|---|
| | NUMBER OF | ASSOCIATED WITH | PERCENT OF CRACKED |
| SAMPLE | OBSERVED PADS | CRACKED SUBSTRATES | SUBSTRATES |
| 36°-ROTATION Y-X | 600 | 15 | 2.5% |
| PROPAGATION LiTaO₃ | | | |
| SINGLE CRYSTAL | | | |
| SUBSTRATE | | | |
| 39°-ROTATION Y-X | 600 | 3 | 0.5% |
| PROPAGATION LiTaO₃ | | | |
| SINGLE CRYSTAL | | | |
| SUBSTRATE | | | |
| 46°-ROTATION Y-X | 600 | 0 | 0% |
| PROPAGATION LiTaO₃ | | | |
| SINGLE CRYSTAL | | | |
| SUBSTRATE | | | |
| 48°-ROTATION Y-X | 600 | 0 | 0% |
| PROPAGATION LiTaO₃ | | | |
| SINGLE CRYSTAL | | | |
| SUBSTRATE | | | |
| 52°-ROTATION Y-X | 600 | 0 | 0% |
| PROPAGATION LiTaO₃ | | | |
| SINGLE CRYSTAL | | | |
| SUBSTRATE | | | |
| 64°-ROTATION Y-X | 600 | 0 | 0% |
| PROPAGATION LiNbO₃ | | | |
| SINGLE CRYSTAL | | | |
| SUBSTRATE | | | |

As is apparent from this table, cracks are found in 2.5% and 0.5% of 36° and 39°-rotation Y-X propagation LiTaO₃ single crystal piezo-electric substrates, respectively, whereas no cracks are found in 46°, 48°, 52°-rotation Y-X propagation LiTaO₃ single crystal piezo-electric substrates and 64°-rotation Y-X propagation LiNbO₃ single crystal piezo-electric substrate.

The foregoing results are presumably attributable to differences in internal stress among the epitaxial Al films deposited on the respective substrates. Specifically, it is thought that since the epitaxial Al films formed on the LiTaO₃ substrates having the rotation cut angle equal to or larger than 46° and the LiNbO₃ substrate having the rotation cut angle of 64° had smaller internal stresses, the single crystal piezo-electric substrates did not suffer from cracks around the connection pads. It is thought that the internal stress is caused by lattice misalignment of the hetero epitaxial film to the underlying single crystal, and more specifically, by the location of aluminum (111) shifted from Z-axis of the underlying single crystal piezo-electric substrate, as observed by the X-ray diffraction.

What is claimed is:

1. A surface acoustic wave device including one or more surface acoustic wave element which comprises an interdigital transducer on a single crystal piezo-electric substrate and is flip-chip mounted on a base substrate through metal bumps, wherein:
said interdigital transducer is formed of a laminate film including an underlying layer made of titanium nitride or titanium and an aluminum layer, said underlying layer and said aluminum layer being laminated sequentially on said single crystal piezo-electric substrate, and
said single crystal piezo-electric substrate is a 46°- or more rotation Y-cut X-propagation lithium tantalate substrate.

2. A surface acoustic wave device including one or more surface acoustic wave element which comprises an interdigital transducer on a single crystal piezo-electric substrate and is flip-chip mounted on a base substrate through metal bumps, wherein:
said interdigital transducer is formed of a laminate film including an underlying layer made of titanium nitride or titanium and an aluminum layer, said underlying layer and said aluminum layer being laminated sequentially on said single crystal piezo-electric substrate, and
said single crystal piezo-electric substrate is a 64°-rotation Y-cut X-propagation lithium niobate substrate.

3. A surface acoustic wave device according to claim 1, wherein:
said aluminum layer of said interdigital transducer is in a single crystal structure.

4. A surface acoustic wave device according to claim 2, wherein:
said aluminum layer of said interdigital transducer is in a single crystal structure.

5. A surface acoustic wave device according to claim 1, wherein said aluminum layer of said interdigital transducer is in a twin structure.

6. A surface acoustic wave device according to claim 2, wherein said aluminum layer of said interdigital transducer is in a twin structure.
